(19) United States
(12) Patent Application Publication
(10) Pub. No.: US 2015/0340630 A1
(43) Pub. Date: Nov. 26, 2015

(54) FLEXIBLE ORGANIC THIN-FILM TRANSISTOR AND SENSOR HAVING THE SAME

(71) Applicant: INDUSTRY-ACADEMIC COOPERATION FOUNDATION, YONSEI UNIVERSITY, Seoul (KR)

(72) Inventors: Seong Il Im, Seoul (KR); Pyo Jin Jeon, Seoul (KR); Seung Hee Nam, Seoul (KR)

(21) Appl. No.: 14/461,875

(22) Filed: Aug. 18, 2014

(30) Foreign Application Priority Data
May 23, 2014 (KR) 10-2014-0062251

(51) Int. Cl. H01L 51/00; H01L 27/28; G01L 1/22; H01L 51/05

(52) U.S. Cl. CPC H01L 51/0097; H01L 51/0554; H01L 27/283; G01L 1/22

(57) ABSTRACT

A flexible organic thin-film transistor according to an exemplary embodiment of the present disclosure includes an active layer formed on a flexible substrate from a material having a smaller grain size than 100 nanometers (nm) and arrangement in a herringbone structure.

Also, a sensor according to another exemplary embodiment of the present disclosure includes at least two flexible organic thin-film transistors coupled to be of an inverter type.

### CROSS-REFERENCE TO RELATED APPLICATIONS

This application claims priority under 36 U.S.C. §119 to Korean Patent Application Mo. 10-2014-0082251 filed on May 23, 2014 in the Korean Intellectual Property Office, the disclosure of which is incorporated herein by reference in its entirety.

### TECHNICAL FIELD

The present disclosure relates to a flexible organic thin-film transistor and a sensor having the same, and more particularly, to a flexible organic thin-film transistor implemented to have elasticity and a sensor having the flexible organic thin-film transistor.

### BACKGROUND

Implementation of a flexible device manufactured using a flexible substrate was feasible with the emergence of organic semiconductors. Since a research result that doping of poly acetylene or a conjugated polymer material provides semiconductor properties and electrical conductivity has been reported, research and development of organic semiconductors has been actively made in the field of organic light emitting diodes. Particularly, as set forth in the related literature, organic light emitting diodes are now being applied to various types of portable electronic products and wearable devices.

Along with this, technology development for flexible organic thin-film transistors is active in progress. A flexible organic thin-film transistor has a channel formed using various organic semiconductor compositions, for example, pentacene, polythlophene, and rubrene, with mobility of a similar level to that of a conventional transistor having a channel forming area made of amorphous silicon.

However a device to which a conventional flexible organic thin-film transistor is applied has a drawback in that a performance change of the device by bending does not recover to an original state and rather falls off.

Also, in the case of a sensor to which a conventional flexible organic thin-film transistor is applied, because a resistance change by bending is very small, it is necessary to convert a resistance change amount to voltage using a Wheatstone bridge and amplify it. Thus, the sensor to which the conventional flexible organic thin-film transistor is applied is unfavorable in terms of device integration.

### RELATED LITERATURES

### Patent Literature

(Patent Literature 1) Korean Patent Application Publication No. 2009-0100684

### SUMMARY

To address the foregoing issue, the present disclosure provides a flexible organic thin-film transistor which has an elastic property of recovering to an initial state after bending and may achieve device integration without a separate amplifier circuit.

In another aspect, the present disclosure provides a sensor having a flexible organic thin-film transistor which has an elastic property of recovering to an initial state after bending and may achieve device integration without a separate amplifier circuit.

A flexible organic thin-film transistor according to an exemplary embodiment of the present disclosure includes an active layer formed on a flexible substrate from a material having a smaller grain size than 100 nanometers (nm).

In the flexible organic thin-film transistor according to an exemplary embodiment of the present disclosure, grains of the material may be arranged in a herringbone structure.

In the flexible organic thin-film transistor according to an exemplary embodiment of the present disclosure, the material may include heptazole.

Also, a sensor according to another exemplary embodiment of the present disclosure includes at least two flexible organic thin-film transistors coupled to be of an inverter type.

In the sensor according to another exemplary embodiment of the present disclosure, each of the flexible organic thin-film transistors may include an active layer formed on a flexible substrate from a material having a smaller grain size than 100 nm.

In the sensor according to another exemplary embodiment of the present disclosure, grains of the material may be arranged in a herringbone structure.

In the sensor according to another exemplary embodiment of the present disclosure, the material may include heptazole.

In the sensor according to another exemplary embodiment of the present disclosures the at least two flexible organic thin-film transistors may include a flexible organic thin-film transistor for a load region and a flexible organic thin-film transistor for a driver region, and a gate electrode of the load region and a gate electrode of the driver region may be perpendicular to each other.

The sensor according to another exemplary embodiment of the present disclosure may include a strain gauge.

The features and advantages of the present disclosure will become apparent from the following detailed description with reference to the accompanying drawings.

Prior to the description, it should be understood that the terms or words used in the specification and the appended claims should not be construed as limited to general and dictionary meanings, but interpreted based on the meanings and concepts corresponding to technical aspects of the present disclosure on the basis of the principle that the inventor is allowed to define terms appropriately for the best explanation.

The flexible organic thin-film transistor according to the exemplary embodiment of the present disclosure has an effect of having an elastic property of recovering to an initial state after bending by stress.

The sensor according to the exemplary embodiment of the present disclosure has an effect of being used in a biometric sensor to defect a motion of a human body part through an output voltage, a sensory perception sensor to detect strain with high sensitivity to variation through an output voltage, a wearable device, a flexible display, a detection sensor of a robot, and a wallpaper-type strain gauge to detect a load in the construction field.

### BRIEF DESCRIPTION OF THE DRAWINGS

FIG. 1a is a plane view of a sensor according to an exemplary embodiment of the present disclosure.

FIG. 1b is a cross-sectional view of FIG. 1a taken along the line A˜A.

FIG. 1c is a circuit diagram of the sensor shown in FIG. 1a.

FIG. 2a is a diagram illustrating an example of a bending state of driver thin-film transistor in a sensor according to an exemplary embodiment of the present disclosure.

FIG. 2b is a diagram illustrating an example of a bending state of load thin-film transistor in a sensor according to an exemplary embodiment of the present disclosure.

FIGS. 3a through 3d are gate voltage vs drain current graphs in a bending state of a flexible organic thin-film transistor according to an embodiment example of the present disclosure.

FIGS. 4a and 4b are gate voltage vs drain current graphs in a bending state of a flexible organic thin-film transistor according to a comparative example of the present disclosure.

FIG. 5a is a strain vs output voltage graph in compressive and tensile states of a sensor according to an exemplary embodiment of the present disclosure.

FIG. 5b is an output voltage vs strain graph in bending states of driver thin-film transistor and load thin-film transistor in a sensor according to an exemplary embodiment of the present disclosure.

FIG. 5c is a graph illustrating a gauge factor of a sensor according to an exemplary embodiment of the present disclosure.

FIGS. 8a through 8d are graphs illustrating an output voltage as a function of an input voltage and time in a sensor according to an exemplary embodiment of the present disclosure.

FIGS. 7a through 7d are graphs illustrating an output voltage with a body change detected at a body location where a sensor according to an exemplary embodiment of the present disclosure is attached.

### Detailed Description of Main Elements

| | |
|---|---|
| 110: Flexible substrate | 120: Buffer layer |
| 130: Organic insulating layer | 141: First active layer |
| 142: Second active layer | 151: Drain/gate electrode |
| 152: Second gate electrode | |

### DETAILED DESCRIPTION OF EMBODIMENTS

The objects, particular advantages, and new features of the present disclosure will become apparent from the following detailed description and the exemplary embodiments with reference to the accompanying drawings. In the addition of reference numerals to elements in each drawing of the specification, note that like elements are intended to have as like numbers as possible although indicated in a different drawing. Also, the terms “first” and “second” may be used to describe various elements but the elements should not be limited by the terms. The terminology used herein is only for the purpose of distinguishing one element from another element. Also, in the description of the present disclosure, when it is deemed that certain detailed description of related art may unnecessarily obscure the essence of the disclosure, its detailed description is omitted herein.

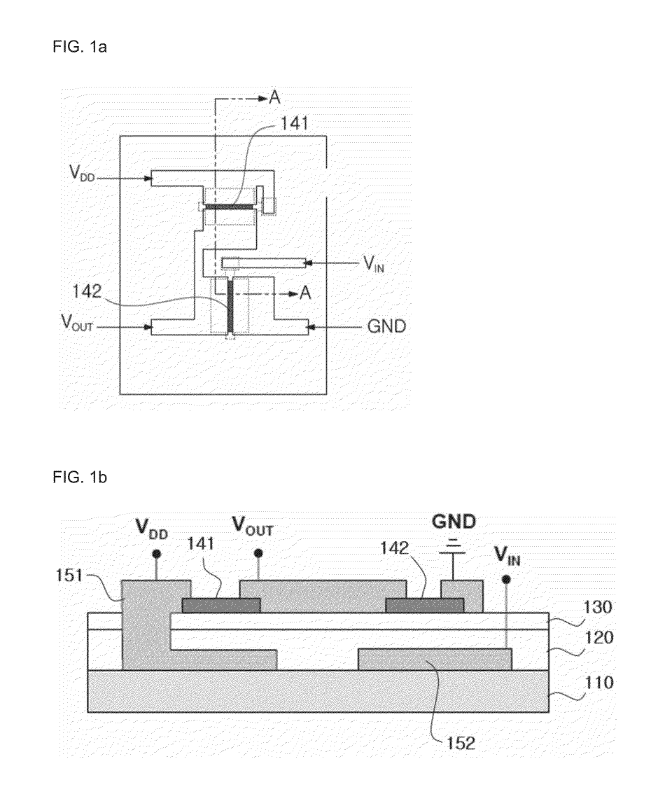

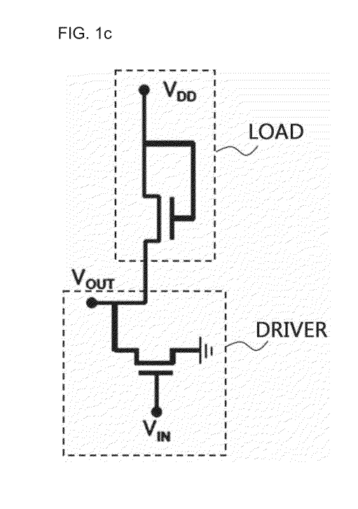

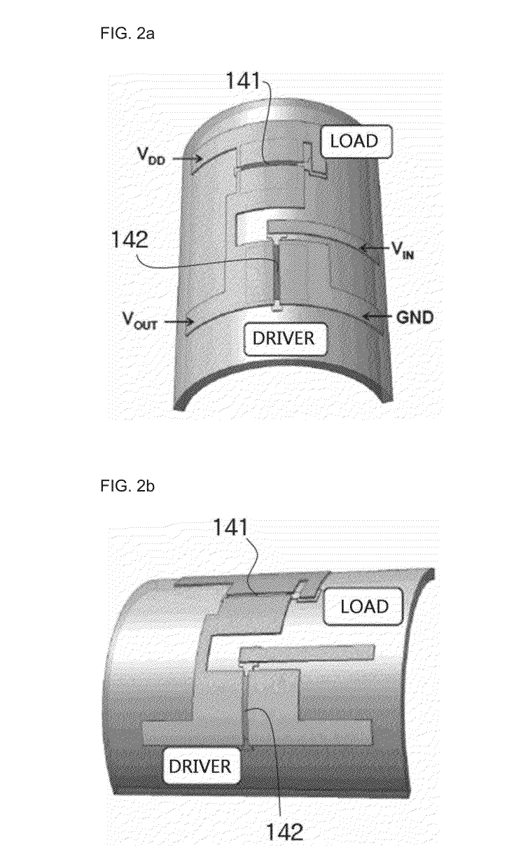

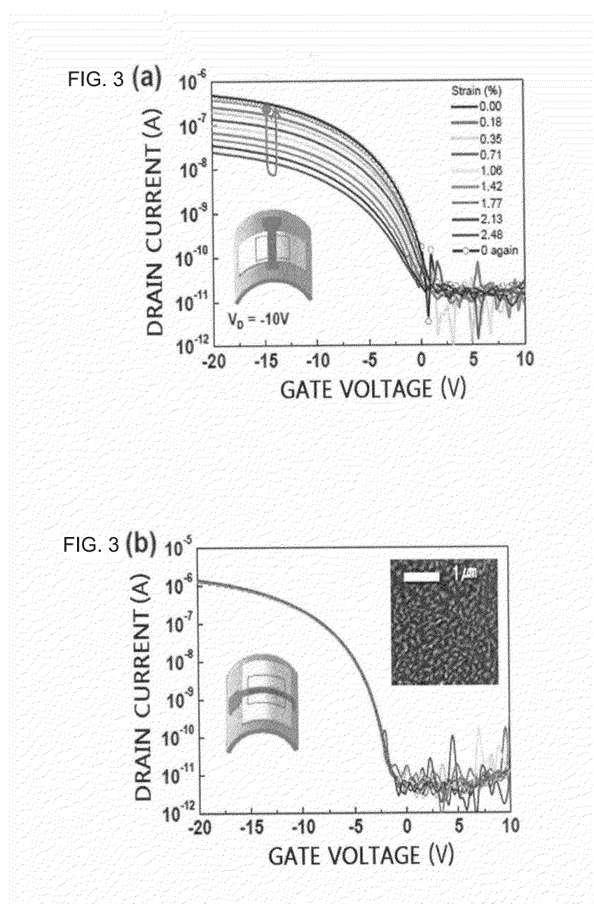

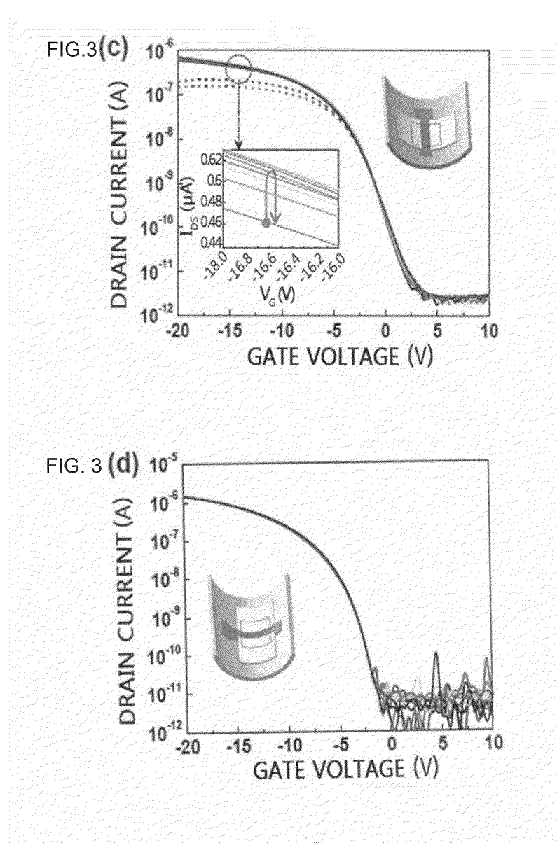

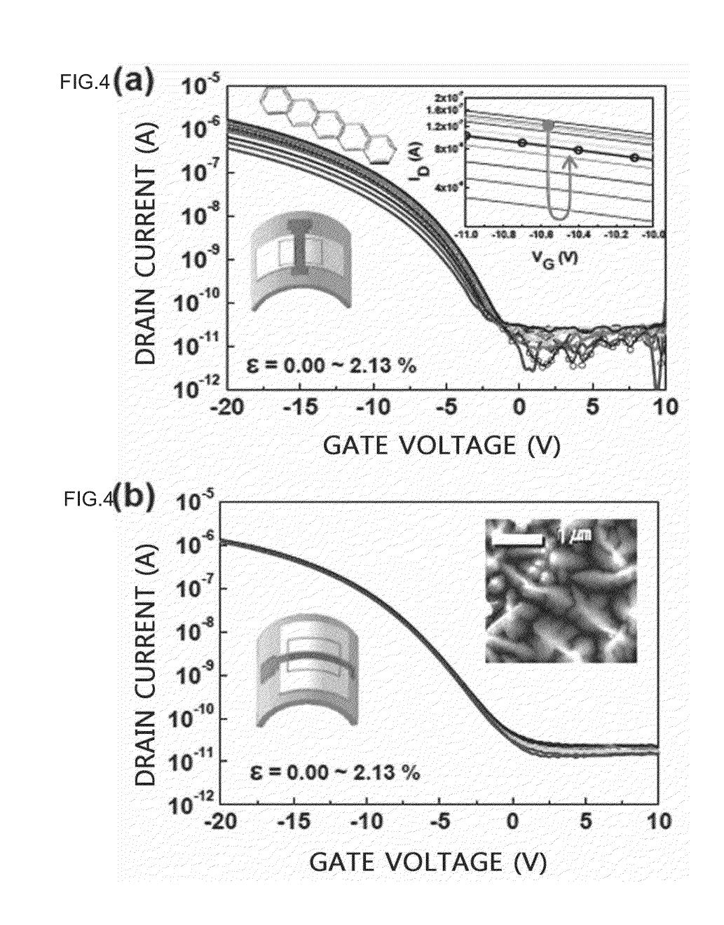

Hereinafter, exemplary embodiments of the present disclosure will be described in detail with reference to the accompanying drawings. FIG. 1a is a plane view of a sensor according to an exemplary embodiment of the present disclosure, FIG. 1b is a cross-sectional view of FIG. 1a taken along the line A˜A, FIG. 1c is a circuit diagram of the sensor shown in FIG. 1a, FIG. 2a is a diagram illustrating an example of a bending state of driver in a sensor according to an exemplary embodiment of the present disclosure, FIG. 2b is a diagram illustrating an example of a bending state of load in a sensor according to an exemplary embodiment of the present disclosure, and FIG. 3 is a gate voltage vs drain current graph in a bending state of a flexible organic thin-film transistor according to an embodiment example of the present disclosure.

The sensor according to the exemplary embodiment of the present disclosure is described, given as an example an inverter-type strain gauge composed of a load region and a driver region including two flexible organic thin-film transistors, as shown in FIGS. 1 a through 1c.

Specifically, the sensor according to the exemplary embodiment of the present disclosure includes a buffer layer 120 and an organic insulating layer 130 formed on a flexible substrate 110, a first active layer 141 and a second active layer 142 provided on an upper surface of the organic insulating layer 130, a drain/gate electrode 151 formed through the buffer layer 120 and the organic insulating layer 130 while being in contact with the first active layer 141, and a second gate electrode 152 embedded in the buffer layer 120 on the flexible substrate 110.

The flexible substrate 100 is a substrate which is made from synthetic resin such as, for example, polyimide, and is flexible, and any material having flexibility may be used.

The buffer layer 120 is a dielectric layer which may apply an electric field to the first active layer 141 and the second active layer 142 by a gate voltage, to control a drain current flowing through the first active layer 141 and the second active layer 142, and may be formed from a material having less defects, for example, Al₂O₃, to have a low leakage current even under tensile stress.

The organic insulating layer 130 may be made from an organic insulating material such as, for example, CYTOP, benzocyclobutene (BCB), or perfluorocyclobutane (PFCB), and particularly, may be formed using CYTOP to form a hydrophobic interface.

The first active layer 141 and the second active layer 142 have characteristics (i) that they are formed from a material having a smaller grain size than 100 nanometers (nm), and (ii) that they are formed from a material in which constituent grains are arranged in a herringbone structure.

The sensor constructed as above according to the exemplary embodiment of the present disclosure is provided, as shown in FIG. 1c, in a type of an inverter circuit having the load region made of the flexible organic thin-film transistor including the first active layer 141 and the driver region made of the flexible organic thin-film transistor including the second active layer 142, and may detect an amount of strain using anisotropy in response to a device bending direction.

That is, using the properties that an on-current dramatically decreases under the vertical direction tensile stress and slightly increases under the vertical direction compressive stress with respect to the gate electrode in the flexible organic thin-film transistor of the driver region as shown in FIG. 2a, while the on-current does not change under the horizontal direction tensile stress and compressive stress with respect to the gate electrode in the flexible organic thin-film transistor of the driver region as shown in FIG. 2b, the sensor according to the exemplary embodiment of the present disclosure may detect a two-dimensional bending direction (vertical or horizontal direction bending) with respect to the gate electrode based on an increase/decrease in output voltage V_{OUT}.

The flexible organic thin-film transistor constituting the sensor according to the exemplary embodiment of the present disclosure needs to have an elastic property of recovering to an initial state after bending by stress, and to do so, the first active layer 141 and the second active layer 142 have the characteristics (i) that they are formed from a material having a smaller grain size than 100 nm, and (ii) that constituent grains are arranged in a herringbone structure.

In this instance, (i) the characteristic that the first active layer 141 and the second active layer 142 are formed from a material having a smaller grain size than 100 nm increases a number of grain boundaries acting as an effective barrier of holes due to the smaller grain size than 100 nm, making it more sensitive to a current variation for same bending, and increases an elastic limit value, causing easier elastic deformation.

Specifically, there a relation between a grain size and elasticity, as seen from a strengthening mechanism of Hall-Petch relation represented by the following Equation 1, where a denominator is a grain size, and as a grain size becomes smaller, a yield stress of a material becomes stronger in proportion to a square root, and thus, an elastic limit increases.

$${σ}_{y} = {σ}_{0} + \frac{{k}_{y}}{\sqrt{d}} \qquad [ Equation 1 ]$$

where σ_{y} denotes a yield stress of a material, σ_{O} denotes a yield stress of a grain, k_{y} denotes a complex parameter for determining an effect of a grain boundary on an increase in yield stress, and d denotes a grain diameter.

Also, (ii) the characteristic that constituent grains in the first active layer 141 and the second active layer 142 are arranged in a herringbone structure provides a sort of buffering effect by the herringbone arrangement structure, so elastic deformation of the flexible organic thin-film transistor is facilitated.

Pentacene and heptazole may be given as an example of a material satisfying (ii) the characteristic that constituent grains are arranged in a herringbone structure, but heptazole is a material also satisfying (i) the characteristic of being formed from a material having a smaller grain size than 100 nm.

The properties of the flexible organic thin-film transistor having the active layer made from heptazole will be described with reference to FIG. 3.

FIG. 3 shows graphs of a correlation between a drain current and a gate voltage detected at a drain voltage V_{D} of −10V applied, respectively, in cases of many bending states in a strain range from 0% to 2.48% and a recovered initial state, and FIG. 3a is a diagram illustrating a graph of a correlation between a drain current and a gate voltage detected respectively in cases of a vertical tensile state with respect to a gate electrode and a recovered initial state, and a chemical structure of heptazole.

As seen from the graph of FIG. 3a, in the vertical tensile state, a flexible organic thin-film transistor having an active layer made from heptazole reduces in drain current in inverse proportion to strain.

Particularly, as indicated by a left top arrow, when a vertical tensile state recovers to an initial state, a drain current defected in a recovered state is the same as a drain current detected in an initial state of 0% strain.

Accordingly, the flexible organic thin-film transistor having the active material made from heptazole according to the exemplary embodiment of the present disclosure has an elastic property of exhibiting the same mechanical property in an initial state and a recovered initial state.

FIG. 3b shows a graph of a correlation between a drain current and a gate voltage defected respectively in cases of a horizontal tensile state with respect to a gate electrode and a recovered initial state, and an atomic force microscopy (AFM) image of heptazole.

As seen from the graph of FIG. 3b, a drain current defected in a horizontal tensile state and a drain current in a recovered initial state are defected as the same without any change, and it can be seen from the AFM image that heptazole has a grain size from 50 nm to 100 nm.

FIG. 3c shows a graph of a correlation between a drain current and a gate voltage detected respectively in cases of a vertical compressive state with respect to a gate electrode and a recovered initial state and a partially enlarged diagram of the graph, and it can be seen from the enlarged diagram of the graph on the left side that when a vertical compressive state recovers to an initial state, a drain current detected in an initial state and a drain current detected in a recovered state are also the same.

Here, a dotted graph of FIG. 3c indicates an elastic buckling failure occurring at a compressive strain of −2.3%.

FIG. 3d shows a graph of a correlation between a drain current and a gate voltage detected respectively in cases of a horizontal compressive state with respect to a gate electrode and a recovered initial state, and similar to the graph of FIG. 3b, a drain current is detected as the same without any change.

Accordingly, when bending is applied horizontally with respect to the gate electrode, the flexible organic thin-film transistor having the active layer made from heptazole according to the exemplary embodiment of the present disclosure has no mechanical change and does not exhibit a strain-induced property.

On the contrary, when bending is applied vertically with respect to the gate electrode, the flexible organic thin-film transistor having the active layer made from heptazole according to the exemplary embodiment of the present disclosure exhibits a strain-induced property after bending, and has an elastic property of exhibiting the same mechanical property in an initial state and a recovered state.

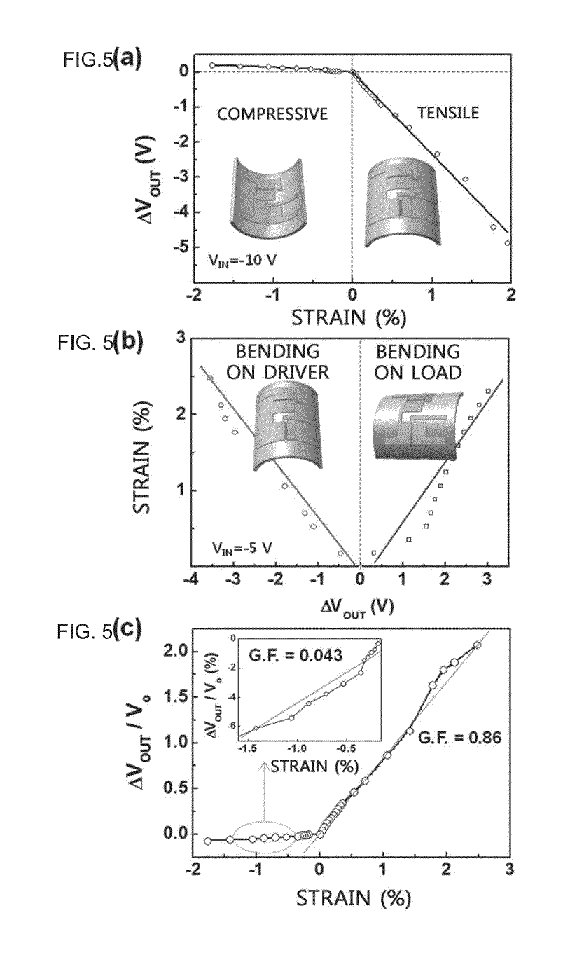

Hereinafter, a comparative example is described with reference to FIG. 4 to specifically compare the elastic property of the flexible organic thin-film transistor according to the exemplary embodiment of the present disclosure. FIG. 4 is a gate voltage vs drain current graph in a bending state of a flexible organic thin-film transistor according to the comparative example of the present disclosure.

The comparative example of the present disclosure uses a flexible organic thin-film transistor having an active layer made from pentacene instead of heptazole, and a drain current as a function of a gate voltage in bending states of various strains is detected and described as shown in FIG. 4.

In the comparative example of the present disclosure, as shown in FIG. 4a, the flexible organic thin-film transistor having the active layer made from pentacene was bent vertically at various strains ε with respect to a gate electrode, and a drain current was detected at various strains ε.

In this instance, as seen from an arrow in an enlarged drain current graph on the right top side of FIG. 4a, a graph of a drain current detected in an initial state and a graph of a drain current detected in a recovered state differ. This difference shows a reduction in elastic capacity of the flexible organic thin-film transistor having the active layer made from pentacene according to the comparative example of the present disclosure.

In contrast, as shown in FIG. 4b, the flexible organic thin-film transistor having the active layer made from pentacene was bent horizontally at various strains ε with respect to a gate electrode, and it can be seen that a drain current detected at each strain ε is defected as the same without any change.

This result is that pentacene satisfies the characteristic of being arranged in a herringbone structure as seen from an AFM image on the right top side of FIG. 4b, but does not satisfy the characteristic of having a smaller grain size than 100 nm, and thus, as in the description of Equation 1, due to a property that as a grain size becomes larger, an elastic limit under tensile stress becomes lower, pentacene does not have an elastic property and reduces in elasticity, unlike heptazole.

Accordingly, the flexible organic thin-film transistor having the active layer made from pentacene according to the comparative example of the present disclosure satisfies (ii) the characteristic that constituent grains are arranged in a herringbone, structure, but does not satisfy (i) the characteristic of a material having a smaller grain size than 100 nm, due to the properties of pentacene, hence it is found that elasticity reduces.

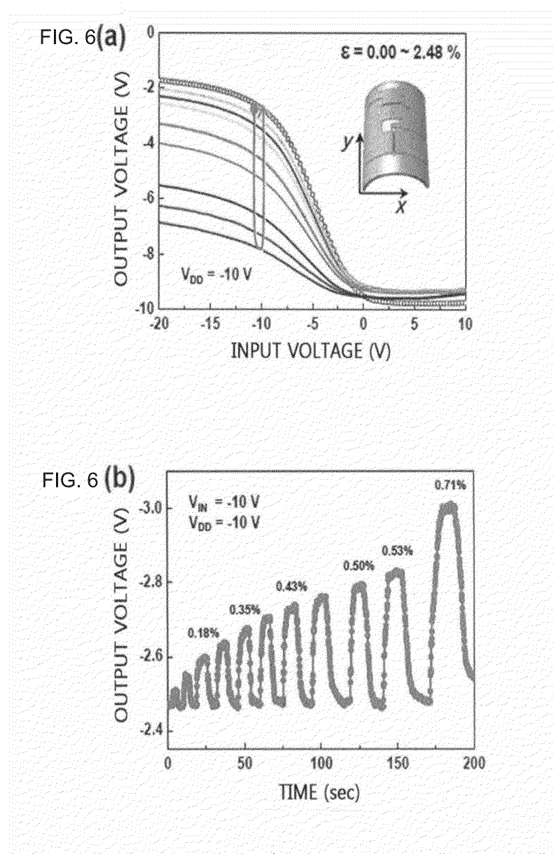

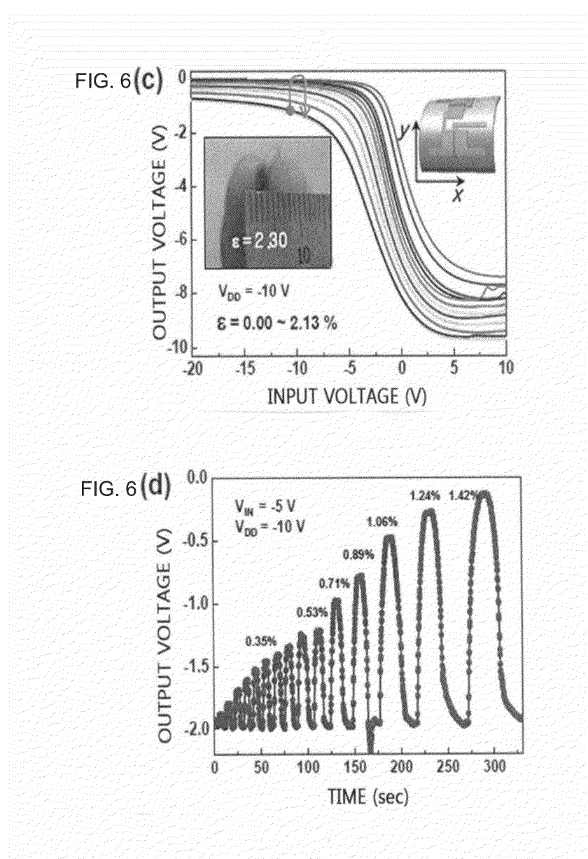

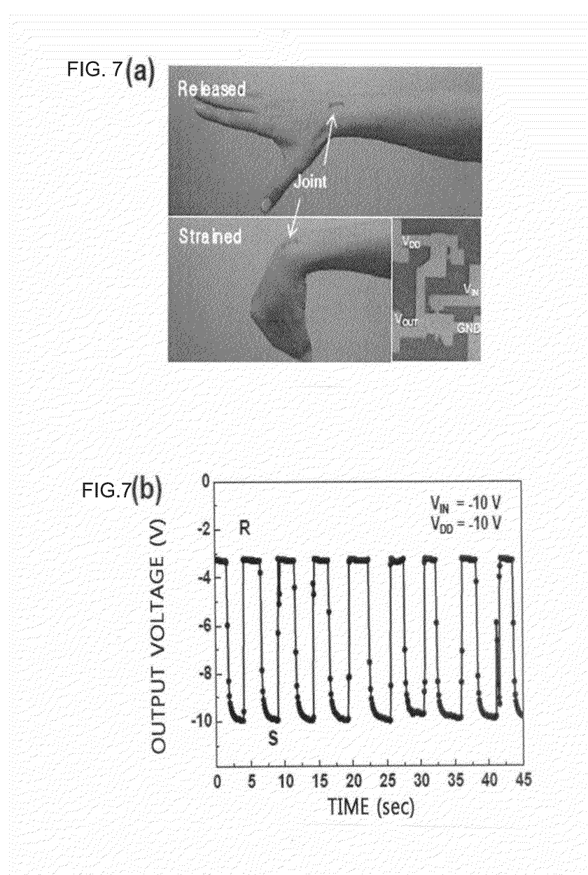

Hereinafter, operating characteristics of the sensor according to the exemplary embodiment of the present disclosure are described with reference to FIGS. 5a through 7. FIG. 5a is a strain vs output voltage graph in compressive and tensile states of the sensor according to the exemplary embodiment of the present disclosure, FIG. 5b is an output voltage vs strain graph in bending states of driver and load in the sensor according to the exemplary embodiment of the present disclosure, FIG. 5c is a graph illustrating a gauge factor of the sensor according to the exemplary embodiment of the present disclosure, FIG. 6 is a graph illustrating an output voltage as a function of an input voltage and time in the sensor according to the exemplary embodiment of the present disclosure, and FIG. 7 is a graph illustrating an output voltage with a body change detected at a body location where the sensor according to the exemplary embodiment of the present disclosure is attached.

The sensor according to the exemplary embodiment of the present disclosure is constructed as an inverter circuit using two flexible organic thin-film transistors having an active layer made from heptazole as shown in FIG. 1a, and may be used as, for example, a strain gauge attached to a muscle and a wrist joint to measure a motion of the muscle and an extent to which the wrist joint is bent.

Accordingly, as shown in FIG. 5a, when detecting an output voltage based on strain in compressive and tensile states of the sensor according to the exemplary embodiment of the present disclosure, an output voltage difference ΔV_{OUT} in a tensile state of 2% strain is detected as great as a maximum, of 5V, but an output voltage difference ΔV_{OUT} in a compressive state of −2% strain is detected as small as 0.15V.

Also, specifically classifying the tensile state, the tensile state may be divided into a vertical tensile bending state of driver with respect to a gate electrode of a driver region as shown on the left side of FIG. 5b and a vertical tensile bending state of load with respect to a gate electrode of a load region as shown on the right side of FIG. 5b.

In the bending state of driver, with the increasing strain, an output voltage difference ΔV_{OUT} decreases when compared to an initial value V_{O}, and in the bending state of load, with the increasing strain, an output voltage difference ΔV_{OUT} increases when compared to an initial value V_{O}. In this instance, a strain and an output voltage difference have a proportional relation in the bending state of load.

Accordingly, a strain based on an output voltage and a bending state such as a bending state of driver and a bending state of load may be detected using the graph of FIG. 5b.

The sensor having this property according to the exemplary embodiment of the present disclosure is measured as having a gauge factor (G,F) of 0.043 in the compressive state and a gauge factor of 0.86 in the tensile state, as shown in FIG. 5c.

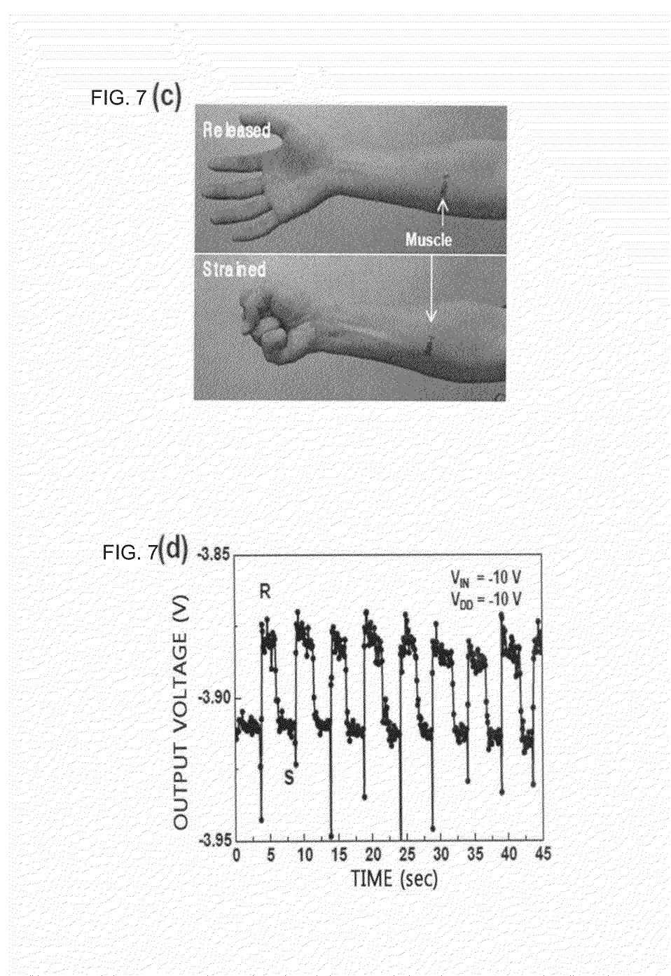

As such, in the bending state of driver in the sensor according to the exemplary embodiment of the present disclosure, that is, in a vertical tensile state of the driver region with respect to the gate electrode and a horizontal tensile state of the load region with respect to the gate electrode, the driver region has a strain-dependent resistance value while the load region has a fixed resistance value, as shown in FIG. 8a.

Accordingly, in the bending state of driver in the sensor according to the exemplary embodiment of the present disclosure, an output voltage detected in a bending state of each strain and a recovered initial state is determined based an input voltage V_{IN} and a tensile strain.

In the bending state of driver, the sensor according to the exemplary embodiment of the present disclosure may detect over time, an extent to which the output voltage changes based on strain as shown in FIG. 6b, and maintains an elastic property even in continuous bending.

On the contrary, as shown in FIG. 6c, in the bending state of load in the sensor according to the exemplary embodiment of the present disclosure, that is, in a horizontal tensile state of the driver region with respect to the gate electrode and a vertical tensile state of the load region with respect to the gate electrode, the driver region has a fixed resistance value while the load region has a strain-dependent resistance value.

Accordingly, in the bending state of load, the sensor according to the exemplary embodiment of the present disclosure may detect, over time, an extent to which the output voltage change based on strain as shown in FIG. 6d, and maintains an elastic property even in continuous bending.

The sensor having this property according to the exemplary embodiment of the present disclosure may be used as a strain gauge attached to a muscle and a wrist joint of a human body to measure a motion of the muscle and an extent to which the wrist joint is bent, as shown in FIG. 7.

For example, as shown in FIG. 7a, the sensor according to the exemplary embodiment of the present disclosure is attached to a wrist joint of a human body, and a motion of straining and releasing a wrist is repeatedly performed, and in this instance, an output voltage over time is defected in a form of a graph shown in FIG. 7b.

Also, as shown in FIG. 7c, the sensor according to the exemplary embodiment of the present disclosure is attached to a muscle part of a human body, and a motion of contraction and relaxation of a muscle is repeatedly performed, and in this instance, an output voltage over time is detected in a form of a graph shown in FIG. 7d.

Accordingly, the sensor according to the exemplary embodiment of the present disclosure may be used as a biometric sensor as a strain gauge to detect a motion of a human body part through an output voltage. Also, the sensor according to the exemplary embodiment of the present disclosure may be used as a sensory perception sensor using strain defection with high sensitivity to variation through an output voltage, a wearable device, a flexible display, a detection sensor in robotics and the like, and a wallpaper-type strain gauge to detect a load in the construction field.

While the technical aspects of the present disclosure have been described with reference to the exemplary embodiments, note that the above embodiments are for the purpose of illustration only and hot intended to limit the scope of the disclosure.

Also, it will be apparent to those skilled in the art that various changes and modifications may be made within the spirit and scope of the disclosure.

1. A flexible organic thin-film transistor, comprising:
an active layer formed on a flexible substrate from a material having a smaller grain size than 100 nanometers (nm).

2. The flexible organic thin-film transistor according to claim 1, wherein grains of the material are arranged in a herringbone structure.

3. The flexible organic thin-film transistor according to claim 2, wherein the material includes heptazole.

4. A sensor comprising at least two flexible organic thin-film transistors coupled to be of an inverter type.

5. The sensor according to claim 4, wherein each of the flexible organic thin-film transistors comprises an active layer formed on a flexible substrate from a material having a smaller grain size than 100 nanometers (nm).

6. The sensor according to claim 5, wherein grains of the material are arranged in a herringbone structure.

7. The sensor according to claim 6, wherein the material includes heptazole.

8. The sensor according to claim 4, wherein the at least two flexible organic thin-film transistors comprise a flexible organic thin-film transistor for a load region and a flexible organic thin-film transistor for a driver region, and a gate electrode of the load region and a gate electrode of the driver region are perpendicular to each other.

9. The sensor according to claim 4, wherein the sensor includes a strain gauge.
